(19) United States
(12) Patent Application Publication
(10) Pub. No.: US 2006/0094155 A1
(43) Pub. Date: May 4, 2006

(54) Method of manufacturing a wafer assembly

(76) Inventors: Joseph Jerome Leibenguth, Saint-Cloud (FR); Beatrice Bonvalot, Meylan (FR); Benoit Thevenot, Olivet (FR); Laurent Lemoullec, Paris (FR); Frederie Depoutot, Grenoble (FR); Yves Reignoux, Saint-Andre (FR)

Correspondence Address: OSHA LIANG L.L.P., 1221 MCKINNEY STREET, SUITE 2800, HOUSTON, TX, 77010, US

(21) Appl. No.: 10/528,249

(22) PCT Filed: Sep. 17, 2003
(86) PCT No.: PCT/IB03/04012

§ 371 Date: Sep. 30, 2005

(30) Foreign Application Priority Data
Sep. 17, 2002 (EP) 02292278.5
Sep. 17, 2002 (EP) 02292279.3
Sep. 24, 2002 (EP) 02292344.5

(51) Int. Cl. H01L 21/50; H01L 21/48; H01L 21/44

(52) U.S. Cl. 438/106

(57) ABSTRACT

A method of manufacturing a wafer assembly involves a chip wafer onto which a cover wafer is deposited, the chip wafer includes an active face and an inactive face, the active face includes chip elements, the cover wafer being provided with a chip-element-receiving cavity located above a chip element, the method involves the following steps: a cover-wafer-depositing step, in which a cover wafer is deposited on the active face so as to obtain a wafer assembly, the cover wafer being provided with plurality of chip-receiving cavities, a chip-receiving cavity being located above a chip element, the cover wafer being made of an organic material, and a wafer assembly thinning step, in which the inactive face of the chip wafer is thinned.

### FIELD OF THE INVENTION

The invention concerns a method of manufacturing a wafer assembly comprising a chip wafer onto which a cover wafer is deposited. The invention also concerns a method of manufacturing a portable device comprising a support layer provided with a cavity. The portable device can be, for example, a smart card or a Subscriber Identification Module (SIM) card.

### BACKGROUND OF THE INVENTION

WO 00/63836 discloses an integrated circuit device comprising an active layer made of semiconductor material; an integrated circuit having one active surface of said active layer, whereby the integrated circuit has circuit elements and at least one contact flush with said active surface; an additional layer fixed to the active surface, whereby said additional layer at least partially covers the integrated surface of the active layer. A hole is made in the addtitional layer, whereby said hole is perpendicular to at least one circuit element.

### SUMMARY OF THE INVENTION

It is an object of the invention to allow both a reduction of the cost and an enhanced quality.

According to an aspect of the invention, a method of manufacturing a wafer assembly comprising a chip wafer onto which a cover wafer is deposited, the chip wafer comprising an active face and an inactive face, the active face comprising chip elements, the cover wafer being provided with a chip-element-receiving cavity located above a chip element, the method comprising the following steps:
a cover-wafer-depositing step, in which a cover wafer is deposited on the active face so as to obtain a wafer assembly, the cover wafer being provided with a plurality of chip-receiving cavities, a chip-receiving cavity being located above a chip element, the cover wafer being made of an organic material;
a wafer assembly thinning step, in which the inactive face of the chip wafer is thinned.

The chip wafer comprises, for example, GSM chip. The chip receiving cavity is arranged to receive, for example, an RF chip.

By thinning the chip wafer, RF chips can be stacked on each GSM chip of the chip wafer so as to obtain a plurality of chip assemblies the thickness of which is susbtantially the same as a non-thinned GSM chip. In addition the cover wafer enables strengthening the thinned chip wafer thus reducing the risk of damages, for example, during the manifacturing process. As the cover wafer is made of an organic material, the cover wafer can be easily deposited using, for example, well-known spin-coating depositing processes. Futhermore, the invention avoids designing a unique integrated circuit comprising the functionalities of both the GSM chip and the RF chip.

The invention thus allows both a reduction of the costs and an enhanced quality.

### BRIEF DESCRIPTION OF THE DRAWINGS

FIG. 1 illustratres a first chip wafer (CHIPW1);

FIG. 2 illustratres a coating-depositing step;

FIG. 3 illustratres a first opening-creating step;

FIG. 4 illustratres a cover wafer (COV);

FIG. 5 illustratres a second opening-creating step;

FIG. 6 illustrates a cover-wafer-depositing step;

FIG. 7 illustrates a wafer-assembly-thinning step;

FIG. 8 illustratres a second chip wafer;

FIG. 9 illustratres a second-chip-wafer-cutting step;

FIG. 10 illustratres a chip-placing step;

FIG. 11 illustratres a chip-assembly-fixing step;

FIG. 12 illustrates a connecting step;

FIG. 13 illustrates a resin-depositing step.

### DETAILED DESCRIPTION

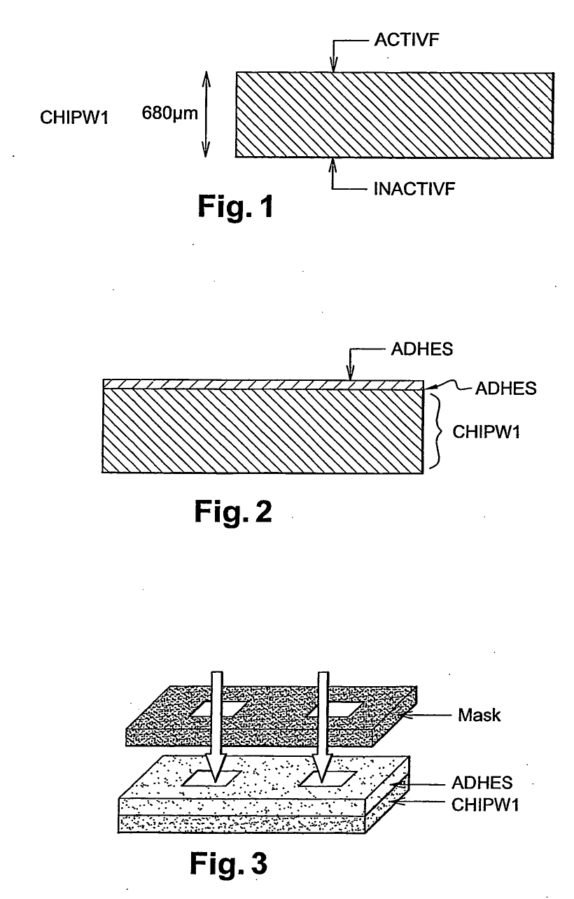

As illustrated in FIG. 1, a first chip wafer (CHIPW1) having a thickness of, for example, 680 μm is used. The first chip wafer (CHIPW1) comprises an active face (ACTIVF) provided with chip elements and an inactive face (INACTIVF). The chip elements can be, for example, GSM chips, that is to say chips designed to be used in a mobile phone. The wafer is made, for example, of silicon.

As illustrated in FIG. 2, if needed, in a coating-depositing step, an adhesive layer (ADHES) is deposited on the active face (ACTIVF) of the first chip wafer (CHIPW1). The adhesive layer, comprises, for example, a polymer. The polymer, can be, for example, a photosensitive polymer.

As illustrated in FIG. 3, in a first opening-creating step, openings are created in the photosensitive polymer using a mask and UV.

As illustrated in FIG. 4, a cover wafer (COV) having a thickness of, for example, 280 μm is used. The cover wafer (COV) can be made of any other material that can be etched, for example, a photosensitive material. It can be, for example, Benzo Cyclo Butène (BCB), a polyimide material, or well-known epoxy based material.

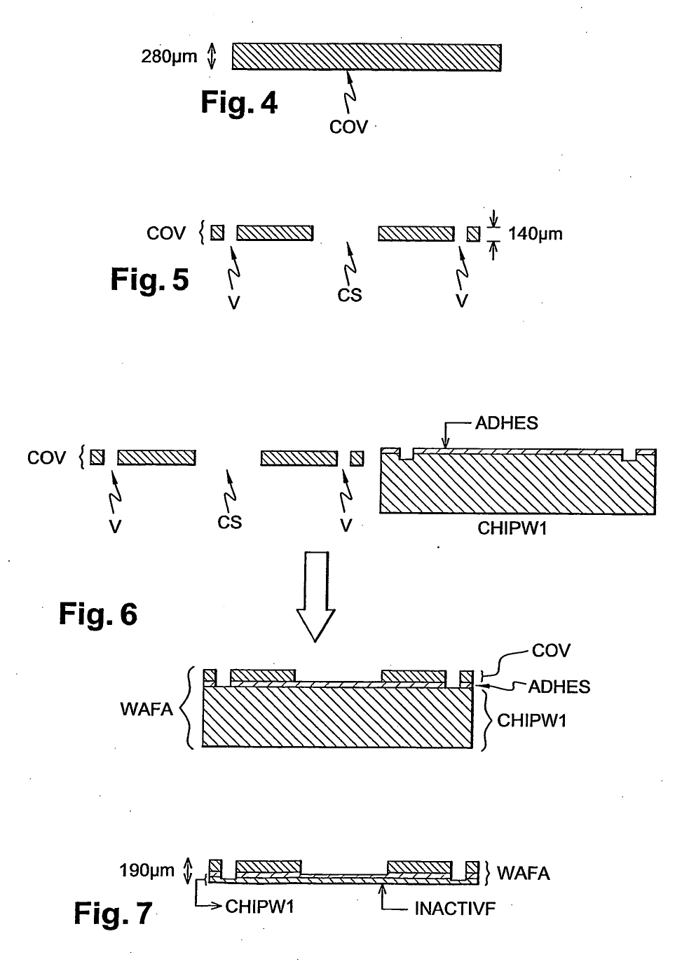

As illustrated in FIG. 5, in a second opening-creating step, vias (V) and chip-receiving cavities (CS) are created in the cover wafer. The second opening-creating step can be done, for example, using etching techniques. In particular, wet etching techniques or dry etching techniques can be used. In a cover-wafer-thinning step, the cover wafer is thinned, for example, to 140 μm.

As illustrated in FIG. 6, in a cover-wafer-depositing step, the cover wafer (COV) is deposited on the adhesive layer (ADHES) of the first chip wafer (CHIPW1) so as to fix the cover wafer (COV) on the first chip wafer (CHIPW1). A wafer-assembly (WAFA) is thus obtained. If there is no adhesive layer, the cover wafer can be directly deposited on the active face of the chip wafer. Advantageously the cover wafer is an organic layer. The cover layer can thus be directly deposited on the active face of the chip wafer using, for example, spin-coating techniques. Advantageously the cover wafer is a photosensitive material so that openings can be esaily created using well-known etching techniques.

As illustrated in FIG. 7, in a wafer-assembly-thinning step, the wafer-assembly (WAFA) is thinned down to, for example, 190 μm at the level of the inactive face (INACTIVF) of the first chip wafer (CHIPW1). The wafer-assembly-thinning step can be done using, for example, a polishing device. The cover wafer allows strengthenning the thus thinned wafer-assembly. In addition, as the cover wafer has a thickness greater than 10 μm, advantageously greater than 100 μm, for example 140 μm, it is easy to manipulate the waffer-assembly during the manufacturing process.

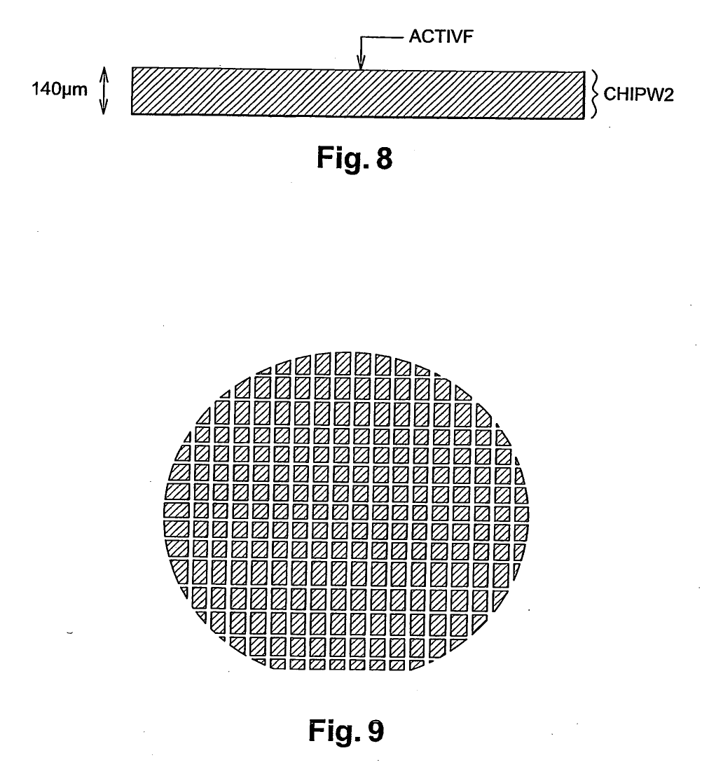

As illustrated in FIG. 8, a second chip wafer (CHIPW2) is used. The second chip wafer (CHIPW2) comprises an active face (ACTIVF) provided with chip elements. The chip elements can be, for example, RF chips. In a second-wafer-thinning step, the second chip wafer is thinned down to, for example, 140 μm.

As illustrated in FIG. 9, in a second-chip-wafer-cutting step, the second chip wafer is cut so as to obtain separated RF chips.

As illustrated in FIG. 10, in a chip-placing step, the separated RF chips are placed in the chip-receiving cavities (CS) of the wafer assembly (WAFA).

In a wafer-assembly cutting step, the wafer assembly comprising the RF chips is then cut so as to obtain separated chip assembly (CHIPA) comprising a GSM chip on which is stacked an RF chip.

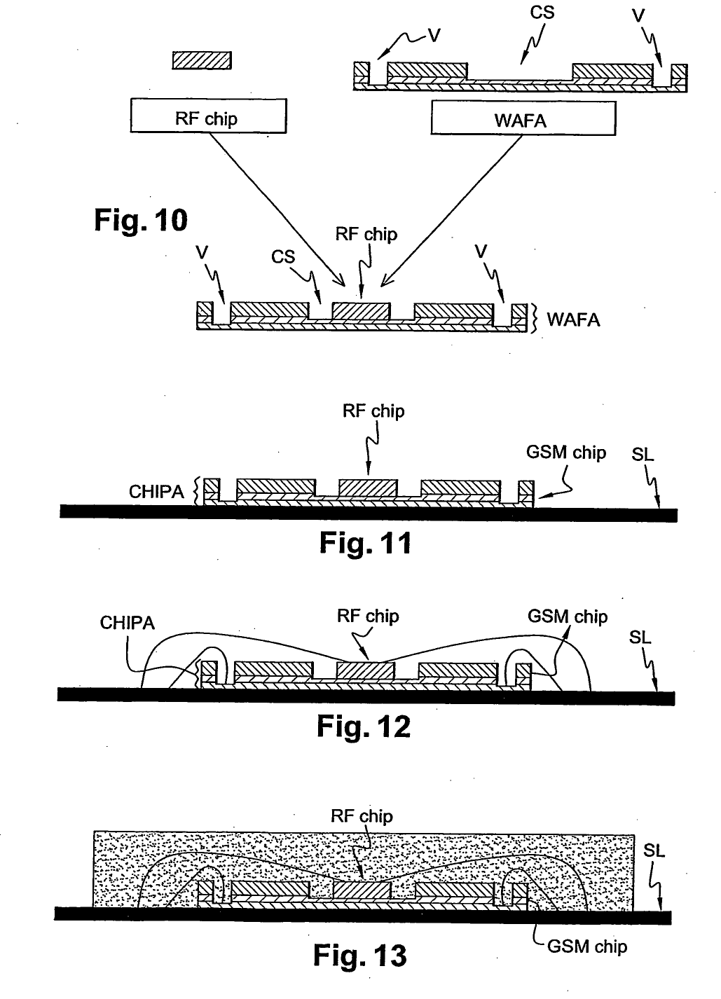

As illustrated in FIG. 11, in a chip-assembly-fixing step, a chip assembly (CHIPA) is fixed on a support layer (SL) comprising contact pads. The support layer comprises, for example, epoxy resin.

As illustrated in FIG. 12, in a connecting step, the RF chip and the GSM chip of a chip assembly (CHIPA) are connected to the contact pads of the support layer (SL) using bonding wires.

As illustrated in FIG. 13, in a resin-depositing step, a resin material is deposited on a chip assembly and the bonding wires so as to protect them.

The description hereinbefore illustrates a method of manufacturing a wafer assembly comprising a chip wafer onto which a cover wafer is deposited, the chip wafer comprising an active face and an inactive face, the active face comprising chip elements, the cover wafer being provided with a chip-element-receiving cavity located above a chip element, the method comprising the following steps:
a cover-wafer-depositing step, in which a cover wafer is deposited on the active face so as to obtain a wafer assembly, the cover wafer being provided with a plurality of chip-receiving cavities, a chip-receiving cavity being located above a chip element, the cover wafer being made of an organic material;
a wafer assembly thinning step, in which the inactive face of the chip wafer is thinned.

The chips or chip elements can be, for example, RF chips, or chips comprising functionalities for the reducing of the risk of current analysis based attacks (=DPA chips). GSM chips, memory chips, Micro Electrical Mechanical Systems (MEMS), silicon sensors, Micro Optical Electrical Mechanical Systems (MOEMS) or any other type of integrated circuits can also be used.

The invention also concerns a method of manufacturing a portable device comprising a support layer provided with a cavity. The method comprises a chip-assembly-fixing step, in which a chip-assembly according to the invention is fixed in the cavity.

1. A method of manufacturing a wafer assembly comprising a chip wafer onto which a cover wafer is deposited, the chip wafer comprising an active face and an inactive face, the active face comprising chip elements, the cover wafer being provided with a chip-element-receiving cavity located above a chip element, the method comprising the following steps:
a cover-wafer-depositing step, in which the cover wafer is deposited on the active face so as to obtain a wafer assembly, the cover wafer being provided with a plurality of chip-receiving cavities, a chip-receiving cavity being located above a chip element, the cover wafer being made of an organic material; and
a wafer assembly thinning step, in which the inactive face of the chip wafer is thinned.

2. The method according to claim 1, wherein the method further comprises a chip-fixing step, in which a chip is fixed in a chip-receiving cavity.

3. The method according to claim 1, wherein the cover wafer is made of a photosensitive material.

4. The method according to claim 3, wherein the photosensitive material comprises Benzo cyclo Butène.

5. The method according to claim 3, wherein the photosensitive material comprises a polyimide.

6. The method according to claim 3, wherein the photosensitive material comprises an epoxy-based material.

7. The method according to claim 2, wherein the method further comprises a wafer-assembly-cutting step, in which the wafer assembly is cut so as to obtain a plurality of chip assembly, a chip assembly comprising the chip element onto which a chip is fixed.

8. The method according to claim 2, wherein the chip element is a GSM chip.

9. The method according to claim 2, wherein the chip is a RF chip.

10. The method according to claim 2, wherein the chip is a DPA chip.

11. Method of manufacturing a portable device comprising a support layer provided with a cavity, the method comprising:
a cover-wafer-depositing step, in which a cover wafer is deposited on an active face so as to obtain a wafer assembly, the cover wafer being provided with a plurality of chip-receiving cavities, a chip-receiving cavity being located above a chip element, the cover wafer being made of an organic material;
a wafer assembly thinning step, in which an inactive face of the chip wafer is thinned;
a chip-fixing step, in which a chip is fixed in a chip-receiving cavity;
a wafer-assembly-cutting step, in which the wafer assembly is cut so as to obtain a plurality of chip assembly, a chip assembly comprising the chip element onto which a chip is fixed; and
a chip-assembly-fixing step, in which the chip assembly is fixed in the cavity.

12. A chip assembly comprising:
a chip wafer onto which a cover wafer is deposited, wherein the chip wafer comprises an active face and an inactive face, and wherein the active face comprises a plurality of chip elements;
a wafer assembly obtained when the cover wafer is deposited on the active face, wherein the wafer assembly is configured to be cut so as to obtain a plurality of chip assembly, the chip assembly comprising at least one of the plurality of chip elements onto which a chip is fixed; and
a chip-element-receiving cavity located above at least one of the plurality of chip elements on the cover wafer,
wherein the cover wafer is provided with a plurality of chip-receiving cavities,
wherein a chip-receiving cavity is located above at least one of the chip elements,
wherein the cover wafer is made of an organic material,
wherein the inactive face of the chip wafer is thinned, and
wherein the chip is fixed in the chip-receiving cavity.
